(19) United States
(12) Patent Application Publication
(10) Pub. No.: US 2026/0293456 A1
(43) Pub. Date: Sep. 24, 2026

(54) SEMICONDUCTOR DEVICE, DISPLAY DEVICE, PHOTOELECTRIC CONVERSION DEVICE, AND ELECTRONIC EQUIPMENT

(71) Applicant: CANON KABUSHIKI KAISHA, Tokyo (JP)

(72) Inventor: YUSUKE KAWAI, Kanagawa (JP)

(21) Appl. No.: 19/542,836

(22) Filed: Feb. 18, 2026

(30) Foreign Application Priority Data
Mar. 21, 2025 (JP) 2025-046383

(51) Int. Cl. H10K 59/127; G06F 1/16; H04N 23/63

(52) U.S. Cl. CPC H10K 59/1275; G06F 1/1629; H04N 23/63

(57) ABSTRACT

A semiconductor device includes a first substrate having an element region where a functional element is disposed, a light-transmissive substrate overlapping at least a portion of the element region when the first substrate is viewed in plan view, and a second substrate having an operating circuit for the functional element. The first substrate and the light-transmissive substrate are bonded to each other, the second substrate is disposed on a side opposite to the first substrate side with respect to the light-transmissive substrate, and the first substrate and the second substrate are electrically connected via wiring formed in the light-transmissive substrate.

### BACKGROUND

### Field of the Technology

The present disclosure relates to a semiconductor device, a display device, a photoelectric conversion device, and electronic equipment.

### Description of the Related Art

A display device having elements such as organic light-emitting elements is lightweight and thin, has characteristics such as a high contrast and a fast response speed, and is widely used as a display. In the display device, a light-transmissive substrate is provided on a display device substrate provided with display elements such as the organic light-emitting elements. In addition, as the resolution of the display device becomes higher, an improvement of a processing speed is required of the display device. For this reason, mounting of a highly integrated drive circuit chip on a display substrate (chip-on-chip mounting) may be adopted.

However, in the chip-on-chip mounting, it is necessary to separately provide a mounting region for the drive circuit chip on the display substrate. For this reason, it has been necessary to secure a sufficient space for the mounting region in an outside portion other than the display region.

International Publication WO 98/005999 discloses a display device including a pair of substrates facing each other with a liquid crystal being interposed therebetween and a drive IC directly bonded to one of the pair of substrates. International Publication WO 98/005999 has a projecting portion that is outwardly projecting to bond the drive IC to an end portion of the other of the pair of substrates, and therefore has a problem in that the space of a peripheral region around the outside portion of the display region is enlarged.

### SUMMARY

The present disclosure provides a technology that can reduce a wiring area used for a functional element to save space, and can reduce the size of a semiconductor device.

According to some embodiments, a semiconductor device include a first substrate having an element region where a functional element is disposed, a light-transmissive substrate overlapping at least a portion of the element region when the first substrate is viewed in plan view, and a second substrate having an operating circuit for the functional element, wherein the first substrate and the light-transmissive substrate are bonded to each other, wherein the second substrate is disposed on a side opposite to the first substrate side with respect to the light-transmissive substrate, and wherein the first substrate and the second substrate are electrically connected via wiring formed in the light-transmissive substrate.

According to some embodiments, a semiconductor device includes a first substrate having an element region where a functional element is disposed, a light-transmissive substrate overlapping at least a portion of the element region when the first substrate is viewed in plan view, and a second substrate having an operating circuit for the functional element, wherein the first substrate and the light-transmissive substrate are bonded to each other, wherein the second substrate is disposed on the first substrate side with respect to the light-transmissive substrate, and wherein the first substrate and the second substrate are electrically connected by wiring formed on the first substrate side of the transmissive substrate.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are diagrams illustrating a schematic configuration of a semiconductor device according to a first embodiment.

FIGS. 2A to 2F are diagrams schematically illustrating a manufacturing method of the semiconductor device according to the first embodiment.

FIG. 3 is a diagram illustrating a schematic configuration of a semiconductor device according to a second embodiment.

FIG. 4 is a diagram illustrating a schematic configuration of a semiconductor device according to a third embodiment.

FIG. 5 is a diagram illustrating a schematic configuration of a semiconductor device according to a fourth embodiment.

FIG. 6 is a diagram illustrating a schematic configuration of a semiconductor device according to a fifth embodiment.

FIG. 7 is a diagram illustrating a schematic configuration of a semiconductor device according to a sixth embodiment.

FIG. 8 is a diagram illustrating a schematic configuration of a semiconductor device according to a seventh embodiment.

FIGS. 9A and 9B are schematic cross-sectional views illustrating an example of a display device according to an embodiment.

FIG. 10 is a schematic diagram illustrating an example of the display device according to the embodiment.

FIGS. 11A and 11B are schematic diagrams illustrating an example of an image capturing device and electronic equipment according to the embodiment.

FIGS. 12A and 12B are schematic diagrams illustrating an example of a display device according to the embodiment.

FIGS. 13A to 13C are schematic diagrams illustrating an example of a lighting device and a moving body according to the embodiment.

FIGS. 14A and 14B are schematic diagrams illustrating an example of a wearable device according to the embodiment.

FIGS. 15A and 15B are schematic diagrams illustrating an example of a display device according to the embodiment.

### DESCRIPTION OF THE EMBODIMENTS

The following modes are intended to embody the technical idea of the present disclosure, and do not limit the present disclosure. Sizes of and positional relationships between members shown in the drawings may be exaggerated to clarity the description. In the following description, the same components are denoted by the same reference numerals, and descriptions thereof may be omitted.

Hereinbelow, referring to the drawings, embodiments of the present disclosure will be described in detail. In the following description, terms which indicate specific directions or positions (e.g., “up", “down", “right”, “left", and other terms including such terms) are used as necessary. Such terms are used for ease of understanding of the embodiments with reference to the drawings, and are not intended to limit the technical scope of the present disclosure by the meanings of the terms.

### First Embodiment

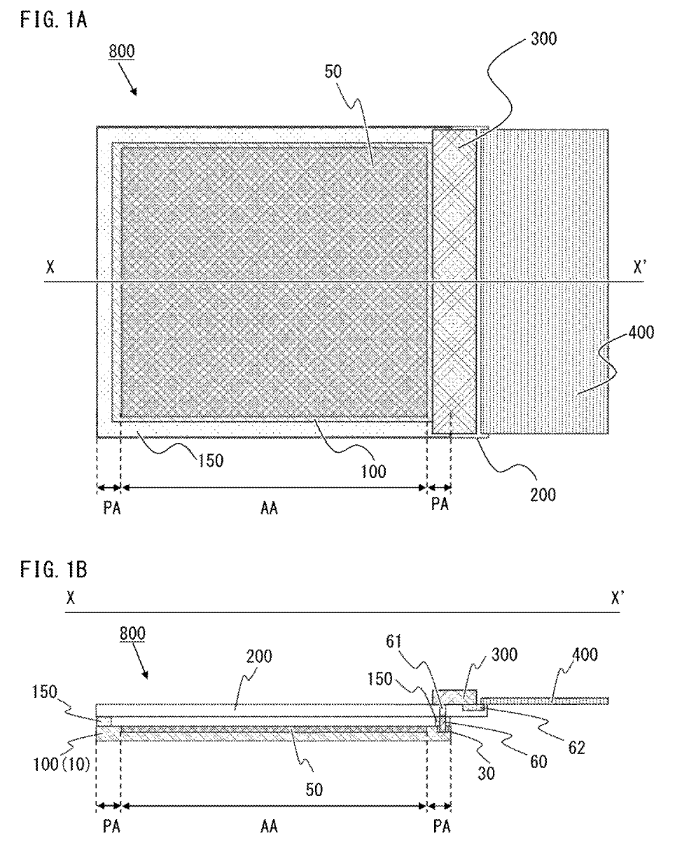

FIG. 1A is a plan view of a semiconductor device 800 according to the first embodiment when viewed in plan view. The semiconductor device 800 is, for example, a display device or a photoelectric conversion device. Here, the wording "in plan view" refers to viewing the semiconductor device 800 from a direction perpendicular to a main surface of a first substrate 100 (a normal direction to the main surface and a stacking direction). It is assumed that, when viewed in plan view, a plurality of members overlapping in the direction perpendicular to the main surface of the first substrate 100 can be seen through. For example, when viewed in plan view, the light-transmissive substrate 200 overlaps the first substrate 100. In addition, a direction (facing direction) in which the light-transmissive substrate 200 faces the first substrate 100 is a direction (normal direction to the main surface) perpendicular to the main surface of the first substrate 100.

As shown in FIG. 1A, the first substrate 100 has an effective element region AA and a peripheral region PA on a first main surface of the first substrate 100. The effective element region AA is provided with an effective element 50, which is a functional element. The peripheral region PA is located around the effective element region AA.

The peripheral region PA includes, for example, a peripheral circuit region (not shown) in which peripheral circuits are provided. In a case where the semiconductor device 800 is a display device, the peripheral circuits include processing circuits (circuits for processing signals to be input to effective pixels) such as, e.g., a drive circuit (circuit for driving an effective region) and a DAC (digital-to-analog conversion circuit). The peripheral region PA is located outside the effective element region AA and includes, e.g., a non-effective element region (not shown) provided with a non-effective element. The non-effective element is an element other than the functional element, which is an element that does not function as the effective element (such as, e.g., a dummy element, a reference element, a test element, or a monitor element).

A bonding member 150 is placed between the light-transmissive substrate 200 and the first substrate 100 to bond the light-transmissive substrate 200 to the first substrate 100. The bonding member 150 is provided in the peripheral region PA of the first substrate 100. The bonding member 150 is disposed at a position surrounding the effective element region AA when viewed in plan view. Meanwhile, a second substrate 300 is disposed on a side the light-transmissive substrate 200 opposite to a surface side thereof facing a junction surface with the first substrate 100, i.e., the first substrate 100 side with respect to the light-transmissive substrate 200, and is electrically connected to the first substrate.

As shown in FIG. 1A, when viewed in plan view, the second substrate 300 overlaps each of the light-transmissive substrate 200, the first substrate 100, and the bonding member 150. Also, when viewed in plan view, the light-transmissive substrate 200 is disposed so as to overlap at least a portion of the effective element region AA of the first substrate 100.

FIG. 1B is a cross-sectional view of the semiconductor device 800 taken along a line X-X' in FIG. 1A. As shown in FIG. 1B, the semiconductor device 800 includes the first substrate 100, the light-transmissive substrate 200, the second substrate 300, a flexible substrate 400, the bonding member 150, an electrode 60, an electrode 61, an electrode 62, and a terminal portion 30. Note that the electrode 61 is formed so as to penetrate through the light-transmissive substrate 200.

The first substrate 100 includes the terminal portion 30 and the effective element 50, which is the functional element. The effective element region AA of the first substrate 100 is provided with the effective element 50. Meanwhile, the peripheral region PA of the first substrate 100 is provided with the terminal portion 30 and the peripheral circuits (not shown).

Meanwhile, the light-transmissive substrate 200 faces the first substrate 100. Here, the light-transmissive substrate 200 faces an upper surface of the first substrate 100 so as to cover the entire effective element region AA and at least a portion of the peripheral region PA when viewed in plan view. For the light-transmissive substrate 200, any material having light transmissiveness (such as, e.g., glass, acrylic, crystal, or sapphire) can be used but, in the present embodiment, alkali-free glass is used.

On a main surface (each or either of the both main surfaces) of the light-transmissive substrate 200, an Anti-Reflection film (AR film) may also be formed. When the effective element 50 is a photoelectric conversion element, due to the anti-reflection film formed on the main surface of the light-transmissive substrate 200, an improvement of the efficiency of light incidence on the effective element 50 can be expected. Meanwhile, when the effective element 50 is a display element, due to the anti-reflection film formed on the main surface of the light-transmissive substrate 200, an improvement of the efficiency of extraction of display light from the effective element 50 can be expected.

The second substrate 300 is a circuit substrate provided with an operating circuit for driving the effective element 50. The operating circuit may include a signal processing circuit or an amplification circuit for the effective element 50. In addition, the second substrate 300 is electrically connected to the electrode 61 penetrating through the light-transmissive substrate 200, and further to the first substrate 100 via the terminal portion 30 and the electrode 60. Furthermore, on the surface of the second substrate 300 facing the light-transmissive substrate 200, an electrode (not shown) made of an Au bump, Au, Cu, or the like is provided.

The flexible substrate 400 is a flexible circuit substrate (such as a glass epoxy substrate or a polyimide film) provided with a wiring pattern, which is a substrate on which a wiring pattern for operating the effective element 50 is mounted by chip-on-film mounting. On the surface of the flexible substrate 400 facing the light-transmissive substrate 200, an electrode (not shown) is provided. As a material of the electrode, e.g., a metal-based material such as copper, aluminum, silver, gold, or platinum, a ceramic-based material such as a carbon-based material such as graphite, carbon nanotube, or graphene, ITO (indium tin oxide), titanium oxide, or a nitride-based material, or the like is used. The flexible substrate 400 is bonded so as to overlap at least a portion of the light-transmissive substrate 200 on the surface of the light-transmissive substrate 200 to which the second substrate 300 is bonded.

The bonding member 150 is provided in the peripheral region PA of the first substrate 100 to bond the first substrate 100 to the light-transmissive substrate 200. The bonding member 150 further covers the terminal portion 30 provided in the peripheral region PA of the first substrate 100 and at least a portion of the electrode 60 provided on the terminal portion 30.

(Detailed Configuration of First Substrate 100) Next, a description will be given of a detailed configuration of the first substrate 100. The first substrate 100 has the terminal portion 30, the effective element 50, and the electrode 60. The first substrate 100 is formed of a semiconductor such as monocrystalline silicon.

The terminal portion 30 includes, e.g., a multi-layer wiring layer and a plug. As the multi-layer wiring layer of the terminal portion 30, an aluminum layer, a copper layer, or the like may be adopted. As the plug of the terminal portion 30, a via plug or a contact plug may be adopted.

The effective element 50 is the display element, the photoelectric conversion element, or the like. As the display element which is the effective element 50, an EL (Electro Luminescence) element in an ELD (Electro Luminescent Display) or the like can be used. It is assumed that, in the present embodiment, the effective element 50 is driven as the display element. The non-effective element may also have a structure similar to that of the effective element.

On the effective element 50 (light-transmissive substrate 200 side), a passivation film for preventing entry of moisture, oxygen, or the like, a color filter layer, a lens structure, or the like can be provided appropriately.

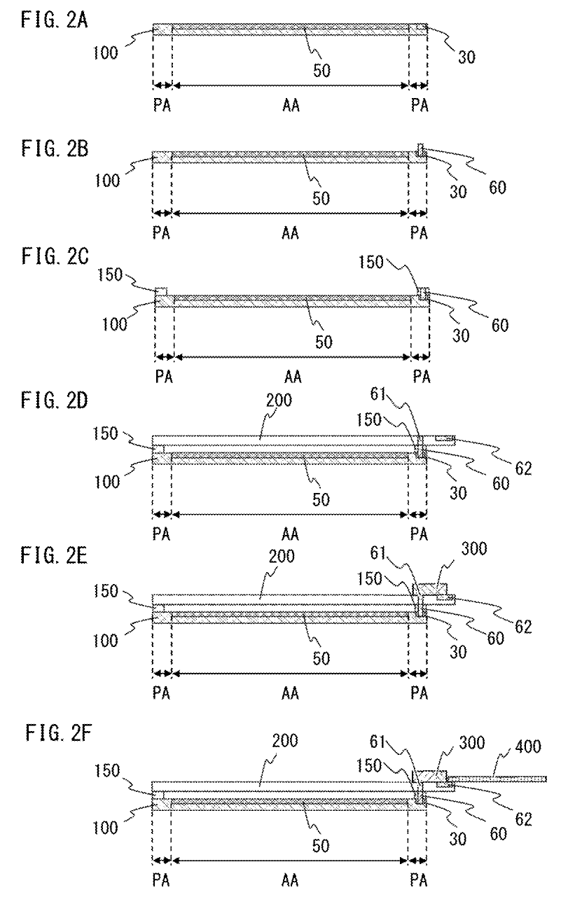

(Manufacturing Method of Organic EL Display Device) A description will be given of a manufacturing method of the semiconductor device 800 when the semiconductor device 800 is an organic EL display device (organic light-emitting element) with reference to FIGS. 2A to 2F. The semiconductor device 800 is manufactured through the following steps (1) to (6).
(1) As shown in FIG. 2A, the first substrate 100 formed of silicon or the like is prepared. On the first substrate 100, the terminal portion 30 and the effective element 50 are disposed.
(2) Next, as shown in FIG. 2B, on the terminal portion 30 provided in the peripheral region PA of the first substrate 100, the at least one electrode 60 is formed. For the electrode 60, an Au bump, a solder, or the like is used.
(3) Next, as shown in FIG. 2C, in the peripheral region PA of the first substrate 100, the bonding member 150 is formed. The bonding member 150 is formed so as to surround the effective element region AA. The bonding member 150 is formed such that a portion thereof on the side where the electrode 60 is provided covers at least a portion of the electrode 60.
(4) Next, as shown in FIG. 2D, the light-transmissive substrate 200 is laminated on the bonding member 150 so as to face the first substrate 100. Here, the at least one electrode 61 is formed so as to penetrate through the light-transmissive substrate 200. The electrode 61 is laminated on the electrode 60 formed at the terminal portion 30 provided in the peripheral region PA of the first substrate 100 so as to come in contact with the electrode 60, and is electrically connected to the electrode 60.
(5) Next, as shown in FIG. 2E, of the main surfaces of the second substrate 300, the main surface on which a junction electrode (not shown) is formed is bonded to a side opposite to the first substrate 100 side, i.e., the side with a junction surface between the first substrate 100 and the light-transmissive substrate 200 with respect to the light-transmissive substrate 200. The second substrate 300 is laminated on the light-transmissive substrate 200 such that the junction electrode of the second substrate 300 comes in contact with the at least one electrode 61 and the at least one electrode 62 which are formed on the light-transmissive substrate 200. As a result, the junction electrode of the second substrate 300 is electrically connected to the electrode 61 and the electrode 62.
(6) Next, as shown in FIG. 2F, of the main surfaces of the flexible substrate 400, the surface formed with the electrode (not shown) is bonded to the same surface of the light-transmissive substrate 200 as the surface thereof to which the second substrate 300 is bonded. Here, the flexible substrate 400 is laminated on the light-transmissive substrate 200 such that the electrode of the flexible substrate 400 comes in contact with the at least one electrode 62 formed on the light-transmissive substrate 200. Thus, the electrode of the flexible substrate 400 is electrically connected to the electrode 62.

According to the manufacturing method including the foregoing steps (1) to (6), the semiconductor device 800 (organic EL display device) according to the present embodiment is completed.

Therefore, as described above, with the semiconductor device 800 in the present embodiment, to the side of the light-transmissive substrate 200 opposite to the first substrate 100 side, the second substrate 300 is bonded. As a result, compared to a case where the bonding member 150 and the second substrate 300 are arranged in parallel, it is possible to save the space of the peripheral region PA of the first substrate 100 and reduce the size of the first substrate 100.

### Second Embodiment

Next, a description will be given of a semiconductor device according to the second embodiment. Note that, in the following description, components that are the same as those in the first embodiment are given the same reference signs, and a detailed description thereof is omitted.

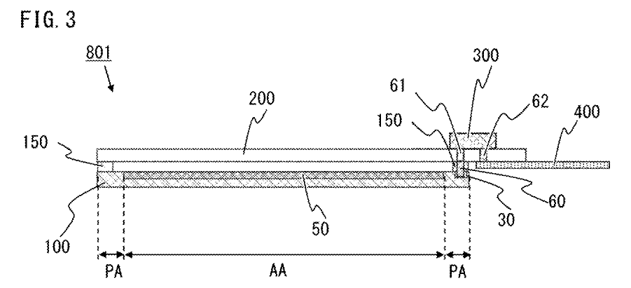

A description will be given of a semiconductor device 801 according to the present embodiment with reference to FIG. 3. In the present embodiment, the flexible substrate 400 is disposed at a position facing the second substrate 300 with the light-transmissive substrate 200 being interposed therebetween.

FIG. 3 illustrates a side view of the semiconductor device 801 according to the present embodiment. FIG. 3 is a diagram corresponding to a cross-sectional view of the semiconductor device 800 taken along the line A-A' in FIG. 1A in the first embodiment. As shown in FIG. 3, the flexible substrate 400 is bonded not to the surface of the light-transmissive substrate 200 that is the same as the surface thereof to which the second substrate 300 is bonded, but to the side thereof opposite to the surface to which the second substrate 300 is bonded.

The electrode 62 is provided so as to penetrate through the light-transmissive substrate 200, and electrically connects the second substrate 300 and the flexible substrate 400.

In the present embodiment, the flexible substrate 400 is bonded to the side of the light-transmissive substrate 200 which is opposite to the surface thereof to which the second substrate 300 is bonded. The electrode 62 is provided so as to penetrate through the light-transmissive substrate 200 and, by the electrode 62, the second substrate 300 and the flexible substrate 400 are electrically connected. Therefore, it can be expected to reduce the wiring areas of the second substrate 300 and the flexible substrate 400 in the light-transmissive substrate 200 for space saving.

### Third Embodiment

Next, a description will be given of a semiconductor device according to the third embodiment. Note that, in the following description, components that are the same as those in the first and the second embodiments are given the same reference signs, and a detailed description thereof is omitted.

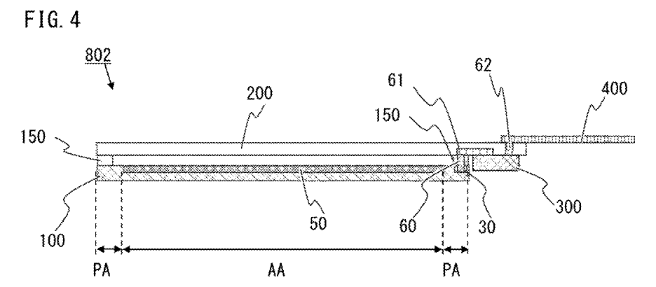

A description will be given of a semiconductor device 802 according to the present embodiment with reference to FIG. 4. In the present embodiment, the second substrate 300 is bonded to the surface of the light-transmissive substrate 200 that is the same as the surface thereof to which the first substrate 100 is bonded. In addition, the electrode 62 is provided so as to penetrate through the light-transmissive substrate 200.

FIG. 4 illustrates a side view of the semiconductor device 802 according to the present embodiment. FIG. 4 is a diagram corresponding to the cross-sectional view of the semiconductor device 800 taken along the line A-A' in FIG. 1A in the first embodiment. As shown in FIG. 4, the second substrate 300 is bonded to a side of the light-transmissive substrate 200 having a junction surface between the first substrate 100 and the light-transmissive substrate 200. In addition, the electrode 62 is provided so as to penetrate through the light-transmissive substrate 200. The flexible substrate 400 is electrically connected to the second substrate 300 via the electrode 62. Accordingly, it can be expected to save the space of the peripheral region PA of the first substrate 100 and reduce the size of the first substrate 100.

In addition, since the second substrate 300 is disposed on the same surface of the light-transmissive substrate 200 as the junction surface between the first substrate 100 and the light-transmissive substrate 200, incident light on the effective element 50 or the light emitted from the effective element 50 is not blocked by the second substrate 300. Therefore, it can be expected to further improve the light-receiving efficiency or light-emitting efficiency of the effective element 50.

### Fourth Embodiment

Next, a description will be given of a semiconductor device according to the fourth embodiment. Note that, in the following description, components that are the same as those in the first to third embodiments are given the same reference signs, and a detailed description thereof is omitted.

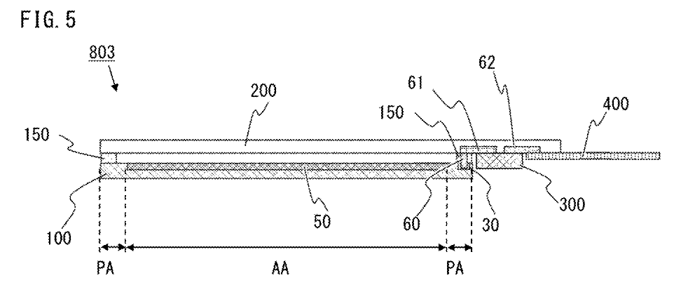

A description will be given of a semiconductor device 803 according to the present embodiment with reference to FIG. 5. In the present embodiment, the second substrate 300 is bonded to a side of the light-transmissive substrate 200 having a junction surface with the first substrate 100. Meanwhile, the electrode 62 is provided on a side of the light-transmissive substrate 200 having a junction surface with the second substrate 300.

FIG. 5 is a side view of the semiconductor device 803 according to the present embodiment. FIG. 5 is a diagram corresponding to the cross-sectional view of the semiconductor device 800 taken along the line A-A' in FIG. 1A in the first embodiment. As shown in FIG. 5, the second substrate 300 is bonded to the surface side of the light-transmissive substrate 200 that is the same as the surface thereof to which the first substrate 100 is bonded. Meanwhile, the electrode 62 is provided on the same surface side of the light-transmissive substrate 200 that is the same as the surface thereof to which the second substrate 300 is bonded. In addition, the flexible substrate 400 is electrically connected to the second substrate 300 via the electrode 62. Accordingly, the second substrate 300 and the flexible substrate 400 are disposed on the same surface side of the light-transmissive substrate 200. As a result, when the second substrate 300 and the first substrate 100 are laminated on the light-transmissive substrate 200, alignment of the electrode 61 and the electrode 62 can be achieved more accurately, and an improvement of the accuracy of the lamination of the first substrate 100, the light-transmissive substrate 200, the second substrate 300, and the flexible substrate 400 can be expected.

### Fifth Embodiment

Next, a description will be given of a semiconductor device according to the fifth embodiment. Note that, in the following description, components that are the same as those in the first to fourth embodiments are given the same reference signs, and a detailed description thereof is omitted.

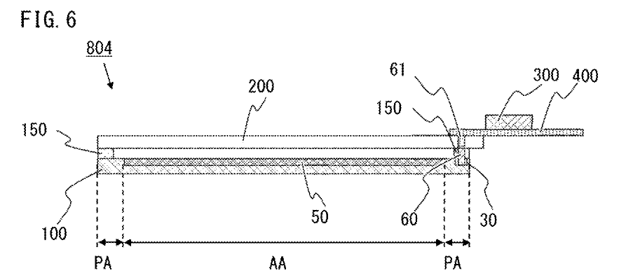

A description will be given of a semiconductor device 804 according to the present embodiment with reference to FIG. 6. In the present embodiment, the second substrate 300 is bonded onto the flexible substrate 400.

FIG. 6 illustrates a side view of the semiconductor device 804 according to the fifth embodiment. FIG. 6 is a diagram corresponding to the cross-sectional view of the semiconductor device 800 taken along the line A-A' in FIG. 1A in the first embodiment. As shown in FIG. 6, the second substrate 300 is bonded onto the flexible substrate 400, and the second substrate 300 and the flexible substrate 400 are electrically connected. In addition, on the flexible substrate 400, an electrode surface (not shown) is disposed so as to face the electrode 61 provided so as to penetrate through the light-transmissive substrate 200, and the flexible substrate 400 and the electrode 61 are electrically connected. Since the second substrate is thus disposed on the flexible substrate, the number of the electrodes formed on the light-transmissive substrate 200 can be reduced to be smaller than that in each of the semiconductor devices according to the first to fourth embodiments.

### Sixth Embodiment

Next, a description will be given of a semiconductor device according to the sixth embodiment. Note that, in the following description, components that are the same as those in the first to fifth embodiments are given the same reference signs, and a detailed description thereof is omitted.

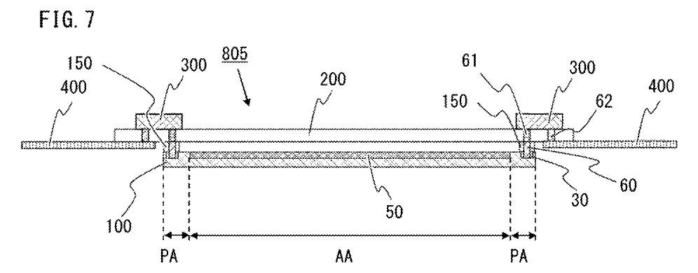

A description will be given of a semiconductor device 805 according to the present embodiment with reference to FIG. 7. In the present embodiment, a plurality of the flexible substrates 400 and a plurality of the second substrates 300 are arranged on the one light-transmissive substrate 200.

FIG. 7 illustrates a side view of the semiconductor device 805 according to the present embodiment. FIG. 7 is a diagram corresponding to the cross-sectional view of the semiconductor device 800 taken along the line A-A' in FIG. 1A in the first embodiment. As shown in FIG. 7, the two second substrates 300 and the two flexible substrates 400 are arranged on the one light-transmissive substrate 200.

In the present embodiment, the second substrates 300 and the flexible substrates 400 are arranged so as to face each other with the light-transmissive substrate 200 being interposed therebetween. However, the second substrates 300 and the flexible substrates 400 may also be arranged on the same surface of the light-transmissive substrate 200. Therefore, as the arrangements of the second substrates 300 and the flexible substrates 400 on the light-transmissive substrate 200, the arrangement shown in each of the first to fifth embodiments described above may also be adopted.

The second substrates 300 and the flexible substrates 400 may or may not be in contact with each other. When the second substrates 300 and the flexible substrates 400 are in contact with each other, the second substrates 300 and the flexible substrates 400 are electrically connected. Meanwhile, when the second substrates 300 and the flexible substrates 400 are not in contact with each other, the second substrates 300 and the flexible substrates 400 are electrically connected via the electrode 62. As shown in FIG. 7, the second substrate 300 is electrically connected to the first substrate 100 via the electrode 61 penetrating through the light-transmissive substrate 200.

Thus, with the semiconductor device 805 in the present embodiment, by bonding the plurality of second substrates 300 to the one light-transmissive substrate 200, it is possible to expect an improvement of display performance of the semiconductor device 805, while saving the space of the peripheral region PA of the first substrate 100 and reducing the size of the first substrate 100.

### Seventh Embodiment

Next, a description will be given of a semiconductor substrate according to the seventh embodiment. Note that, in the following description, components that are the same as those in the first to sixth embodiments are given the same reference signs, and a detailed description thereof is omitted.

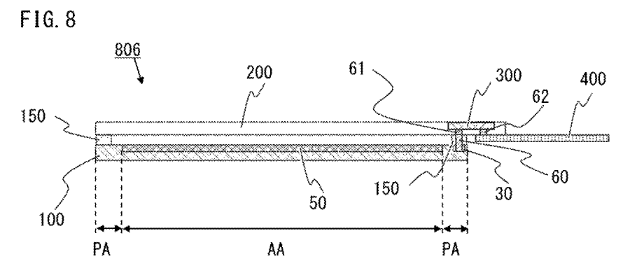

A description will be given of a semiconductor device 806 according to the present embodiment with reference to FIG. 8. In the present embodiment, the light-transmissive substrate 200 is formed with a depressed portion 600. In addition, the second substrate 300 is disposed in the depressed portion 600 formed in the light-transmissive substrate 200.

FIG. 8 illustrates a side view of the semiconductor device 806 according to the present embodiment. FIG. 8 is a diagram corresponding to the cross-sectional view of the semiconductor device 800 taken along the line A-A' in FIG. 1A in the first embodiment. As shown in FIG. 8, one surface of the light-transmissive substrate 200 is formed with the depressed portion 600. In addition, the second substrate 300 is disposed in the depressed portion 600 formed in the light-transmissive substrate 200.

Meanwhile, the electrode 62 is provided so as to penetrate through the light-transmissive substrate 200. The flexible substrate 400 is bonded to the side of the light-transmissive substrate 200 opposite to the surface thereof provided with the depressed portion 600. Moreover, at a position facing the electrode 62, the electrode (not shown) of the flexible substrate 400 is disposed, and the flexible substrate 400 is electrically connected to the electrode 62. The second substrate 300 is electrically connected to the flexible substrate 400 via the electrode 62. In addition, the second substrate 300 is electrically connected to the first substrate 100 via the electrode 61 penetrating through the light-transmissive substrate 200.

Accordingly, with the semiconductor device 806 in the present embodiment, it is possible to save the space of the peripheral region PA of the first substrate 100 and reduce the size of the first substrate 100. Furthermore, since the second substrate 300 is disposed within the depressed portion formed in the light-transmissive substrate 20, the thickness of the semiconductor device 806 can be reduced to be smaller than that in a case where the second substrate 300 is disposed on the surface of the light-transmissive substrate 200.

Next, a description of an organic light-emitting element employed in the semiconductor devices as described above will be given.

[Structure of Organic Light-Emitting Element] An organic light-emitting element produced using the deposition mask 1 of the present embodiment will be explained next. In the present embodiment the organic light-emitting element is provided by forming an insulating layer, a first electrode, an organic compound layer and a second electrode, on a substrate. A protective layer, a color filter, a microlens and so forth may be provided on a cathode. In a case where a color filter is provided, a planarization layer may be provided between the color filter and the protective layer. The planarization layer can be for instance made up of an acrylic resin. The same is true in a case where the planarization layer is provided between the color filter and the microlens.

[Substrate] At least one material selected from quartz, glass, silicon, resins and metals can be used as the material for the substrate that makes up the organic light-emitting element. Switching elements such as transistors and wiring may be provided on the substrate, and an insulating layer may be provided on the foregoing. Any material can be used as the insulating layer so long as a contact hole can be formed between the insulating layer and the first electrode, and insulation from unconnected wiring can be ensured, so that wiring can be formed between the first electrode and the insulating layer. For instance a resin such as a polyimide, or silicon oxide or silicon nitride can be used herein.

[Electrodes] A pair of electrodes can be used as the electrodes of the organic light-emitting element. The pair of electrodes may be an anode and a cathode. In a case where an electric field is applied in the direction in which the organic light-emitting element emits light, the electrode of higher potential is the anode, and the other electrode is the cathode. Stated otherwise, the electrode that supplies holes to the light-emitting layer is the anode, and the electrode that supplies electrons is the cathode.

A material having a work function as large as possible is preferable herein as a constituent material of the anode. For instance single metals such as gold, platinum, silver, copper, nickel, palladium, cobalt, selenium, vanadium or tungsten, and mixtures containing the foregoing metals, can be used in the anode. Alternatively, alloys obtained by combining these single metals, or metal oxides such as tin oxide, zinc oxide, indium oxide, indium tin oxide (ITO) or indium zinc oxide, may be used in the anode. Conductive polymers such as polyaniline, polypyrrole and polythiophene can also be used in the anode.

Any of the foregoing electrode materials may be used singly; alternatively, two or more materials may be used concomitantly. The anode may be made up of a single layer, or may be made up of a plurality of layers.

In a case where an electrode of the organic light-emitting element is configured in the form of a reflective electrode, the electrode material can be for instance chromium, aluminum, silver, titanium, tungsten, molybdenum, or alloys or layered bodies of the foregoing. The above materials can also function as a reflective film not having a role as an electrode. In a case where an electrode of the organic light-emitting element is configured in the form of a transparent electrode, for instance an oxide transparent conductive layer of for instance indium tin oxide (ITO) or indium zinc oxide can be used, although not particularly limited thereto, as the electrode material. The electrodes may be formed by photolithography.

A material having a small work function may be a constituent material of the cathode. For instance alkali metals such as lithium, alkaline earth metals such as calcium, single metals such as aluminum, titanium, manganese, silver, lead or chromium, and mixtures of the foregoing, may be used herein. Alternatively, alloys obtained by combining these single metals can also be used. For instance magnesium-silver, aluminum-lithium, aluminum-magnesium, silver-copper or zinc-silver can be used. Metal oxides such as indium tin oxide (ITO) can also be used. These electrode materials may be used singly as one type, or two or more types can be used concomitantly. Also, the cathode may have a single-layer structure or a multilayer structure. Silver is preferably used among the foregoing, and more preferably a silver alloy, in order to reduce silver aggregation. Any alloy ratio can be adopted, so long as silver aggregation can be reduced. A ratio silver: other metal may be for instance 1:1, or 3:1.

Although not particularly limited thereto, the cathode may be a top emission element that utilizes an oxide conductive layer of ITO or the like, or may be a bottom emission element that utilizes a reflective electrode of aluminum (Al) or the like. The method for forming the cathode is not particularly limited, but more preferably for instance a DC or AC sputtering method is resorted to, since in that case film coverage is good and resistance can be readily lowered.

[Pixel Separation Layer] The pixel separation layer of the organic light-emitting element is formed out of a silicon nitride (SiN) film, a silicon oxynitride (SiON) film, or a silicon oxide (SiO) film, in turn having been formed by chemical vapor deposition (CVD). In order to increase the in-plane resistance of the organic compound layer, preferably the thickness of the organic compound layer that is formed, particularly a hole transport layer, is set to be small at the side walls of the pixel separation layer. Specifically, the side walls can be formed to be thin by increasing vignetting at the time of deposition, through an increase of the taper angle of the side walls of the pixel separation layer and/or an increase of the thickness of the pixel separation layer.

On the other hand, it is preferable to adjust the side wall taper angle of the pixel separation layer and the thickness of the pixel separation layer so that no voids are formed in the protective layer that is formed on the pixel separation layer. The occurrence of defects in the protective layer can be reduced by virtue of the fact that no voids are formed in the protective layer. Since the occurrence of defects in the protective layer is thus reduced, it becomes possible to reduce loss of reliability for instance in terms of the occurrence of dark spots or defective conduction in the second electrode.

The present embodiment allows effectively suppressing leakage of charge to adjacent pixels even when the taper angle of the side walls of the pixel separation layer is not sharp. Studies by the inventors of the present application have revealed that leakage of charge to adjacent pixels can be sufficiently reduced if the taper angle lies in the range at least 60 degrees and not more than 90 degrees. The thickness of the pixel separation layer is preferably at least 10 nm and not more than 150 nm. A similar effect can be achieved also in a configuration having only a pixel electrode lacking a pixel separation layer. In this case, however, it is preferable to set the film thickness of the pixel electrode to be half or less the thickness the organic layer, or to impart forward taper at the ends of the pixel electrode, at a taper angle smaller than 60 degrees, since short circuits of the organic light-emitting element can be reduced thereby.

[Organic Compound Layer] The organic compound layer of the organic light-emitting element may be formed out of a single layer or multiple layers. In a case where the organic compound layer has multiple layers, these may be referred to as a hole injection layer, a hole transport layer, an electron blocking layer, a light-emitting layer, a hole blocking layer, an electron transport layer or an electron injection layer, depending on the function of the layer. The organic compound layer is mainly made up of organic compounds, but may contain inorganic atoms and inorganic compounds. For instance the organic compound layer may have copper, lithium, magnesium, aluminum, iridium, platinum, molybdenum or zinc. The organic compound layer may be disposed between the first electrode and the second electrode, and may be disposed in contact with the first electrode and the second electrode.

In the case of multiple light-emitting layers, the first and second light-emitting layers may have a charge generating portion between the first and second light-emitting layers. The charge generating portion may have an organic compound with a lowest unoccupied molecular orbital energy (LUMO) of -5.0 eV or less. The same is true in the case of providing a charge generating section between the second and third light-emitting layers.

[Protective Layer] A protective layer may be provided on the second electrode. For instance, intrusion of water or the like into the organic compound layer can be reduced, and the occurrence of display defects also reduced, by bonding a glass provided with a moisture absorbent onto the second electrode. As another embodiment, a passivation film of for instance silicon nitride may be provided on the cathode, to reduce intrusion of water or the like into the organic compound layer. For instance, formation of the cathode may be followed by conveyance to another chamber, without breaking vacuum, whereupon a protective layer may be formed through formation of a silicon nitride film having a thickness of 2 μm by CVD. The protective layer may be provided by atomic deposition (ALD), after film formation by CVD. The material of the film formed by ALD is not limited, but may be for instance silicon nitride, silicon oxide or aluminum oxide. Silicon nitride may be further formed, by CVD, on the film having been formed by ALD. The film formed by ALD may be thinner than the film formed by CVD. Specifically, the thickness of the film formed by ALD may be 50% or less, or 10% or less.

[Color Filter] A color filter may be provided on the protective layer of the organic light-emitting element of the present embodiment. For instance a color filter having factored therein the size of the organic light-emitting element may be provided on another substrate, followed by affixing to a substrate having the organic light-emitting element provided thereon; alternatively, a color filter may be patterned by photolithography on the protective layer illustrated above. The color filter may be made up of a polymer.

[Planarization Layer] The organic light-emitting element of the present embodiment may have a planarization layer between the color filter and the protective layer. The planarization layer is provided for the purpose of reducing underlying layer unevenness. The planarization layer may be referred to as a resin layer in a case where the purpose of the planarization layer is not limited. The planarization layer may be made up of an organic compound, which may be a low-molecular or high-molecular compound, preferably a high-molecular compound.

The planarization layer may be provided above and below the color filter, and the constituent materials of the respective planarization layers may be identical or dissimilar. Concrete examples include polyvinylcarbazole resins, polycarbonate resins, polyester resins, ABS resins, acrylic resins, polyimide resins, phenolic resins, epoxy resins, silicone resins and urea resins.

[Microlens] The organic light-emitting element may have an optical member such as a microlens, on the light exit side. The microlens may be made up of for instance an acrylic resin or an epoxy resin. The purpose of the microlens may be to increase the amount of light extracted from the organic light-emitting element, and to control the direction of the extracted light. The microlens may have a hemispherical shape. In a case where the microlens has a hemispherical shape, then from among tangent lines that are in contact with the hemisphere there is a tangent line that is parallel to the insulating layer, such that the point of contact between that tangent line and the hemisphere is the apex of the microlens. The apex of the microlens can be established similarly in any cross section. That is, among tangent lines that are in contact with a semicircle of the microlens in a sectional view, there is a tangent line that is parallel to the insulating layer, such that the point of contact between that tangent line and the semicircle is the apex of the microlens.

A midpoint of the microlens can also be defined. Given a hypothetical line segment from the end point of an arc shape to the end point of another arc shape, in a cross section of the microlens, the midpoint of that line segment can be referred to as the midpoint of the microlens. The cross section for discriminating the apex and the midpoint may be a cross section that is perpendicular to the insulating layer.

The microlens has a first surface with a convex portion and a second surface on the reverse side from that of the first surface. Preferably, the second surface is disposed closer to a functional layer than the first surface. In adopting such a configuration, the microlens must be formed the organic light-emitting element. In a case where the functional layer is an organic layer, it is preferable to avoid high-temperature processes in the manufacturing process. If a configuration is adopted in which the second surface is disposed closer to the functional layer than the first surface, the glass transition temperatures of all the organic compounds that make up the organic layer are preferably 100ºC or higher, and more preferably 130ºC or higher.

[Counter Substrate] The organic light-emitting element of the present embodiment may have a counter substrate on the planarization layer. The counter substrate is so called because it is provided at a position corresponding to the above-described substrate. The constituent material of the counter substrate may be the same as that of the substrate described above. The counter substrate can be used as the second substrate in a case where the substrate described above is used as the first substrate.

[Organic Layer] Each organic compound layer (hole injection layer, hole transport layer, electron blocking layer, light-emitting layer, hole blocking layer, electron transport layer, electron injection layer and so forth) that makes up the organic light-emitting element of the present embodiment is formed in accordance with one of the methods illustrated below.

A dry process such as vacuum deposition, ionization deposition, sputtering, plasma or the like can be used for the organic compound layers that make up the organic light-emitting element of the present embodiment. A wet process in which a layer is formed through dissolution in an appropriate solvent, relying on a known coating method (for instance spin coating, dipping, casting, LB film deposition to inkjet.) can resorted to instead of a dry process.

When a layer is formed for instance by vacuum deposition or by solution coating, crystallization or the like is unlikelier occur; this translates into superior stability over time. In a case where a film is formed in accordance with a coating method, the film can be formed by being combined with an appropriate binder resin.

Examples of binder resins include, although not limited to, polyvinylcarbazole resins, polycarbonate resins, polyester resins, ABS resins, acrylic resins, polyimide resins, phenolic resins, epoxy resins, silicone resins and urea resins. These binder resins may be used singly as one type, in the form of homopolymers or copolymers; alternatively, two or more types of binder resin may be used in the form of mixtures. Additives such as known plasticizers, antioxidants and ultraviolet absorbers may be further used concomitantly, as needed.

[Pixel Circuit] A light-emitting device having the organic light-emitting element of the present embodiment may have pixel circuits connected to respective organic light-emitting elements. The pixel circuits may be of active matrix type, and may control independently emission of light by the first organic light-emitting element and the second organic light-emitting element. Active matrix circuits may be voltage-programmed or current-programmed. A drive circuit has a pixel circuit for each pixel. Each pixel circuit may have an organic light-emitting element, a transistor that controls the emission luminance of the organic light-emitting element, a transistor that controls emission timing, a capacitor which holds the gate voltage of the transistor that controls emission luminance, and a transistor for connection to GND bypassing the light-emitting element.

The light-emitting device has a display area and a peripheral area disposed around the display area. The display area has pixel circuits, and the peripheral area has a display control circuit. The mobility of the transistors that make up the pixel circuits may be lower than the mobility of the transistors that make up the display control circuit.

The slope of the current-voltage characteristic of the transistors that make up the pixel circuits may be gentler than the slope of the current-voltage characteristic of the transistors that make up the display control circuit. The slope of the current-voltage characteristics can be measured on the basis of a so-called Vg-Ig characteristic.

The transistors that make up the pixel circuits are connected to light-emitting elements such as the first organic light-emitting element.

[Pixels] The organic light-emitting element of the present embodiment has a plurality of pixels. The pixels have sub-pixels that emit mutually different colors. The sub-pixels may have for instance respective RGB emission colors.

The pixels emit light in a pixel opening region. This region is the same as the first region. The aperture diameter of the pixel openings may be 15 μm or smaller, and may be 5 μm or larger. More specifically, the aperture diameter of the pixel openings may be for instance 11 μm, or 9.5 μm, or 7.4 μm, or 6.4 μm. The spacing between sub-pixels may be 10 μm or smaller, specifically 8 μm, or 7.4 μm, or 6.4 μm.

The pixels can have any known arrangement in a plan view. For instance, the pixel layout may be a stripe arrangement, a delta arrangement, a penile arrangement or a Bayer arrangement. The shape of the sub-pixels in a plan view may be any known shape. For instance, the sub-pixel shape may be for instance quadrangular, such as rectangular or rhomboidal, or may be hexagonal. Needless to say, the shape of the sub-pixels is not an exact shape, and a shape close to that a of rectangle falls under a rectangular shape. Sub-pixel shapes and pixel arrays can be combined with each other.

[Use of the Organic Light-Emitting Element] The organic light-emitting element according to one embodiment of the present disclosure can be used as a constituent member of a display device or of a lighting device. Other uses of the organic light-emitting element include exposure light sources for electrophotographic image forming apparatuses, backlights for liquid crystal display devices, and light-emitting devices having color filters, in white light sources.

The display device may be an image information processing device having an image input unit for input of image information, for instance from an area CCD, a linear CCD or a memory card, and an information processing unit for processing inputted information, such that an inputted image is displayed on a display unit.

A display unit of an imaging device or of an inkjet printer may have a touch panel function. The driving scheme of this touch panel function may be an infrared scheme, a capacitive scheme, a resistive film scheme or an electromagnetic induction scheme, and is not particularly limited. The display device may also be used in a display unit of a multi-function printer.

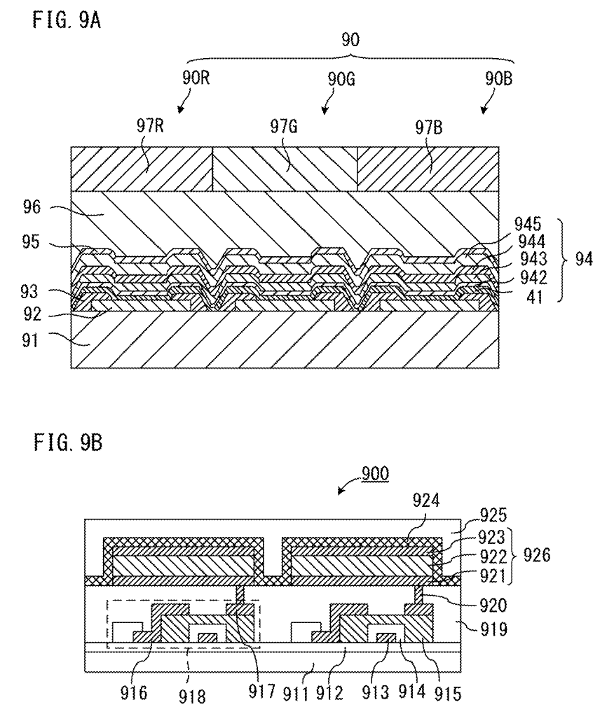

A display device provided with the organic light-emitting element according to the present embodiment will be explained next with reference to accompanying drawings. FIGS. 9A and 9B are cross-sectional schematic diagrams illustrating examples of a display device having organic light-emitting elements and transistors connected to respective organic light-emitting elements. The transistors are an example of active elements. The transistors may be thin-film transistors (TFTs).

FIG. 9A is an example of a pixel, which is a constituent element of a display device having the organic light-emitting element according to the present embodiment. The pixel has sub-pixels 90. The sub-pixels are divided into 90R, 90G and 90B, depending on the respective emission light of the sub-pixel. The emission color may be made different on the basis of the wavelength emitted from the light-emitting layer; alternatively, the light emitted from each sub-pixel may be selectively transmitted or color-converted for instance by a respective color filter. Each sub-pixel has a reflective electrode 92 as a first electrode on an interlayer insulating layer 91, and an insulating layer 93 that covers the edge of the reflective electrode 92. Each sub-pixel has an organic compound layer 94 that covers the reflective electrode 92 and the insulating layer 93, a transparent electrode 95 as a second electrode, a protective layer 96, and a respective color filter 97R, 97G or 97B.

The interlayer insulating layer 91 may have transistors and capacitive elements disposed thereunder or in the interior. The transistors and the first electrode may be electrically connected for instance by way of contact holes (not shown).

The insulating layer 93 is also referred to as a bank or as pixel separation film. The insulating layer 93 is disposed covering the edge of the first electrode while surrounding the first electrode. Portions where the insulating layer is not disposed are in contact with the organic compound layer 94, yielding emission regions.

The organic compound layer 94 has a hole injection layer 941, a hole transport layer 942, a first light-emitting layer 943, a second light-emitting layer 944 and an electron transport layer 945.

The transparent electrode 95, as the second electrode, may be a transparent electrode, a reflective electrode, or a semi-transparent electrode.

The protective layer 96 reduces permeation of moisture into the organic compound layer. The protective layer 96 is illustrated herein in the form of one layer, but may be multiple layers. Each protective layer 96 may have an inorganic compound layer or an organic compound layer.

The color filters 97 are divided into a color filter 97R, a color filter 97G and a color filter 97B, according to the color thereof. The color filters may be formed on a planarization film, not shown. A resin protective layer, not shown, may be provided on the color filters. The color filters may be formed on the protective layer 96. Alternatively, the color filters may be affixed after having been provided on a counter substrate such as a glass substrate.

FIG. 9B illustrates a display device 900 having the organic light-emitting element of the present embodiment. The display device 900 has organic light-emitting elements 926 and TFTs 918 as an example of a transistor. The display device 900 is provided with a substrate 911 made up of glass, silicon or the like, and an insulating layer 912 at the top of the substrate 911. Respective active elements such as TFTs 918 are disposed on the insulating layer, such that a gate electrode 913, a gate insulating film 914 and a semiconductor layer 915 of each active element are disposed therein. Each TFT 918 is also made up of the semiconductor layer 915, a drain electrode 916 and a source electrode 917. An insulating film 919 is provided on the TFTs 918. An anode 921 and a source electrode 917 that make up a respective organic light-emitting element 926 are connected through a contact hole 920 provided in the insulating film.

The method for electrically connecting the electrodes (anode and cathode) included in each organic light-emitting element 926 and the electrodes (source electrode and drain electrode) included in the respective TFT is not limited to the implementation illustrated in FIG. 9B. Specifically, it suffices that either one from among the anode and the cathode be electrically connected to either a TFT source electrode or a TFT drain electrode. The acronym TFT signifies thin-film transistor.

In the display device 900 of FIG. 9B, the organic compound layer is illustrated as one layer, but the organic compound layer 922 may be a plurality of layers. A first protective layer 924 and a second protective layer 925 for reducing deterioration of the organic light-emitting element are provided on the cathode 923.

Although transistors are used as switching elements in the display device 900 of FIG. 9B, other switching elements may be used instead.

The transistors used in the display device 900 of FIG. 9B are not limited to transistors that utilize a single-crystal silicon wafer, and may be thin-film transistors having an active layer on an insulating surface of a substrate. Examples of active layers include single-crystal silicon, non-single-crystal silicon such an amorphous silicon or microcrystalline silicon, as well as non-single-crystal oxide semiconductors such as indium zinc oxide or indium gallium zinc oxide. Thin-film transistors are also referred to as TFT elements.

The transistors included in the display device 900 of FIG. 9B may be formed in a substrate such as a Si substrate. The wording "formed in a substrate" signifies that transistors are produced by processing the substrate itself, for instance a Si substrate. That is, the feature of having transistors in the substrate may signify that the substrate and the transistors are integrally formed with each other.

The emission luminance of the organic light-emitting element according to the present embodiment is controlled by a TFT, which is an example of a switching element; an image can be thus displayed according to respective values of emission luminance, by providing a plurality of organic light-emitting elements within a plane. The switching element according to the present embodiment is not limited to a TFT, and may be a transistor made up of low-temperature polysilicon, or an active matrix driver formed on a substrate such as a Si substrate. The wording “on the substrate” can also signify herein “in the substrate”. The size of the display unit governs the choice of whether the transistors are to be provided in the substrate, or whether TFTs are to be used; if for instance the size of the display unit is about 0.5 inches, it is preferable to provide the organic light-emitting elements on a Si substrate.

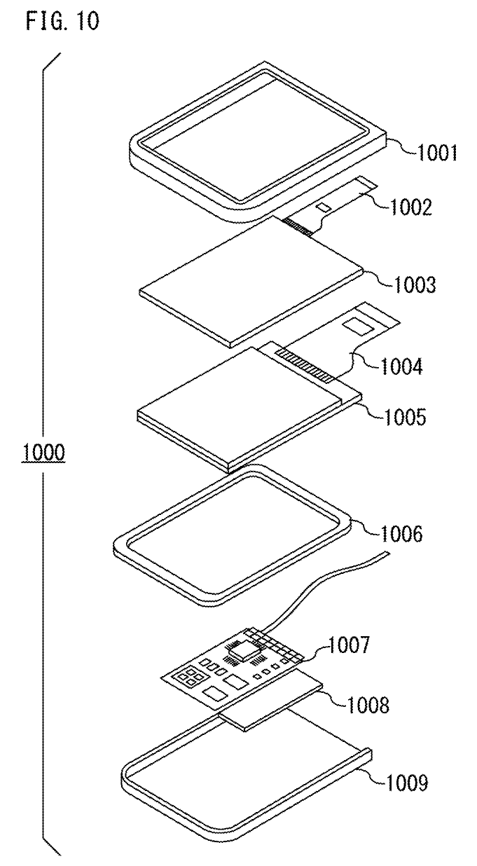

Next, FIG. 10 illustrates a schematic diagram depicting an example of a display device having an organic light-emitting element according to the present embodiment. A display device 1000 may have a touch panel 1003, a display panel 1005, a frame 1006, a circuit board 1007 and a battery 1008, between an upper cover 1001 and a lower cover 1009. The touch panel 1003 and the display panel 1005 are connected to flexible printed circuits FPCs 1002, 1004. Transistors are printed on the circuit board 1007. The battery 1008 may be omitted if the display device is not a portable device; even if the display device is a portable device, the battery 1008 may be provided at a different position.

The display device according to the present embodiment may have red, green and blue color filters. The color filters may be disposed in a delta arrangement of the above red, green and blue.

The display device according to the present embodiment may be used as a display unit of a mobile terminal. In that case the display device may have both a display function and an operation function. Mobile terminals include mobile phones such as smartphones, tablets and head-mounted displays.

The display device according to the present embodiment may be used in a display unit of an imaging device that has an optical unit having a plurality of lenses, and that has an imaging element which receives light having passed through the optical unit. The imaging device may have a display unit that displays information acquired by the imaging element. The display unit may be a display unit exposed outside the imaging device, or may be a display unit disposed within a viewfinder. The imaging device may be a digital camera or a digital video camera.

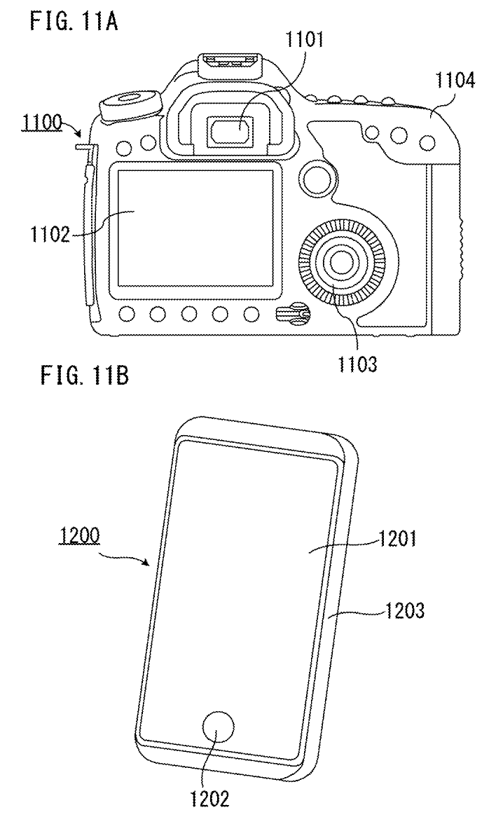

Next, FIG. 11A illustrates a schematic diagram depicting an example of an imaging device having the organic light-emitting element according to one embodiment. An imaging device 1100 may have a viewfinder 1101, a rear display 1102, an operation unit 1103 and a housing 1104. The viewfinder 1101 may have the display device according to the present embodiment. In that case the display device may display not only an image to be captured, but also for instance environment information and imaging instructions. The environment information may include for instance external light intensity, external light orientation, the moving speed of a subject, and the chance of the subject being blocked by an obstacle.

The timing suitable for imaging is short, and hence information should be displayed as soon as possible. It is therefore preferable to configure the display device so as to have high response speed, using the organic light-emitting element of the present embodiment. A display device that utilizes the organic light-emitting element can be utilized more suitably than these devices or liquid crystal display devices, where high display speed is required.

The imaging device 1100 has an optical unit, not shown. The optical unit has a plurality of lenses, and forms an image on an imaging element accommodated in the housing 1104. The lenses can be focused through adjustment of the relative positions thereof. This operation can also be performed automatically. The imaging device may be referred to as a photoelectric conversion device. The photoelectric conversion device can encompass, as an imaging method other than sequential imaging, a method that involves detecting a difference relative to a previous image, and a method that involves cutting out part of a recorded image.

FIG. 11B is a schematic diagram illustrating an example of an electronic device having the organic light-emitting element according to the present embodiment. An electronic device 1200 includes a display unit 1201, an operation unit 1202, and a housing 1203. The housing 1203 may have a circuit, a printed board having the circuit, a battery, and a communication unit. The operation unit 1202 may be a button, or a touch panel-type reaction unit. The operation unit may be a biometric recognition unit which for instance performs unlocking upon recognition of a fingerprint. The electronic device having a communication unit can also be referred to as a communication device. The electronic device 1200 may further have a camera function, by being provided with a lens and an imaging element. Images captured by way of the camera function are displayed on the display unit. Examples of the electronic device include smartphones and notebook computers.

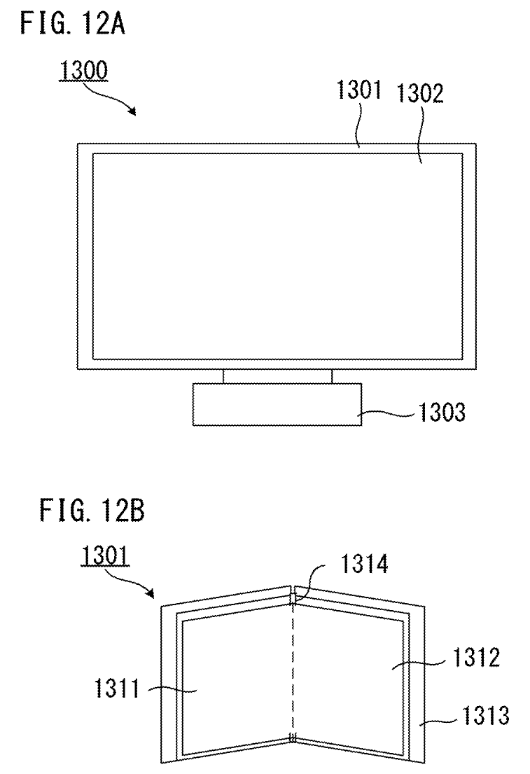

Next, FIGS. 12A and 12B illustrate schematic diagrams depicting examples of a display device having the organic light-emitting element according to one embodiment. FIG. 12A illustrates a display device 1300 such as a television monitor or PC monitor. The display device 1300 has a frame 1301 and a display unit 1302. The display unit 1302 may use the organic light-emitting element according to the present embodiment.

The display device 1300 also has the frame 1301 and a base 1303 that supports the display unit 1302. The form of the base 1303 is not limited to the form in FIG. 12A. The lower side of the frame 1301 may also double as the base.

The frame 1301 and the display unit 1302 may be curved. The radius of curvature of the foregoing may be at least 5000 mm and not more than 6000 mm.

FIG. 12B is a schematic diagram illustrating another example of a display device having the organic light-emitting element according to the present embodiment. A display device 1310 in FIG. 12B is a so-called foldable display device, configured to be foldable. The display device 1310 has a first display unit 1311, a second display unit 1312, a housing 1313 and a folding point 1314. The first display unit 1311 and the second display unit 1312 may have the organic light-emitting element according to the present embodiment. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit and the second display unit may display one image.

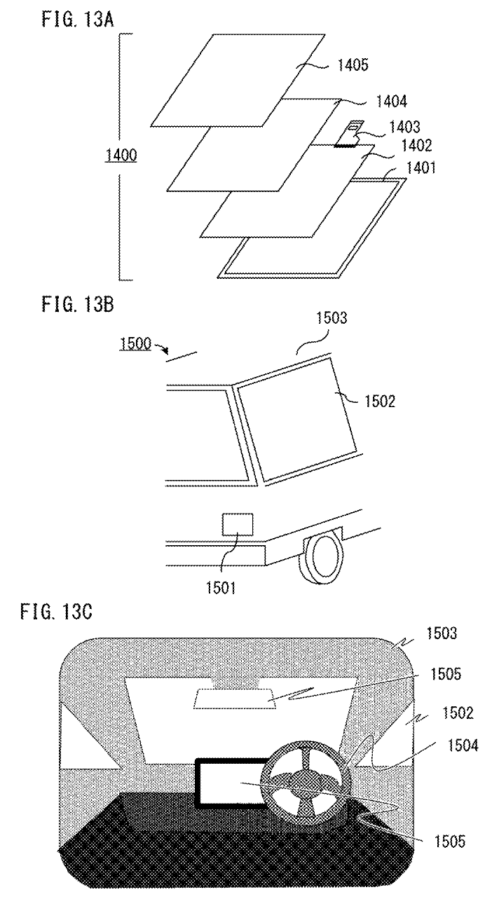

FIG. 13A illustrates a schematic diagram depicting an example of a lighting device having the organic light-emitting element according to one embodiment. A lighting device 1400 may have a housing 1401, a light source 1402, a circuit board 1403, an optical film 1404 and a light-diffusing part 1405. The light source has the organic light-emitting element according to the present embodiment. The optical film may be a filter that enhances the color rendering of the light source. The light-diffusing part allows effectively diffusing light from the light source, and allows delivering light over a wide area, for instance in exterior decorative lighting. The optical filter and the light-diffusing part may be provided on the light exit side of the lighting device. A cover may be provided on the outermost part, as the case may require.

The lighting device 1400 is for instance a device for indoor illumination. The lighting device may emit white, daylight white, or other colors from blue to red. The lighting device may have a light control circuit for controlling light having the foregoing emission colors. The lighting device 1400 may have the organic light-emitting element according to the present disclosure, and a power supply circuit connected thereto. The power supply circuit is a circuit that converts AC voltage to DC voltage. White denotes herein a color with a color temperature of 4200 K, and daylight white denotes a color with a color temperature of 5000 K. The lighting device 1400 may have a color filter. The lighting device 1400 may have a heat dissipation part.

The heat dissipation part dumps, out of the device, heat from inside the device; the heat dissipation part may be made up of a metal or of liquid silicone rubber, exhibiting high specific heat.

FIGS. 13B and 13C illustrate schematic diagrams of an automobile, which is an example of a moving body having the organic light-emitting element according to one embodiment. The automobile 1500 has tail lamps, being an example of a lamp. The automobile 1500 may have a tail lamp 1501, of a form such that the tail lamp is lit up when for instance a braking operation is performed.

The tail lamp 1501 has the organic light-emitting element according to the present embodiment. The tail lamp may have a protective member that protects the organic light-emitting element. The protective member may be made up of any material, so long as the material has a certain degree of high strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503, and a window 1502 attached to the vehicle body 1503. The window may be a transparent display, unless the purpose of the window is to look ahead and behind the automobile. The transparent display may have the organic light-emitting element according to the present embodiment. In that case, constituent materials such as the electrodes of the organic light-emitting element are made up of transparent members.

In addition, as illustrated in FIG. 13C, the automobile 1500 includes a steering wheel 1504 for controlling the direction of movement of the moving body, and a display unit 1505 mounted on the vehicle body 1503, which displays maps, the position of the moving body, the direction of turns, and the like. The display unit 1505 may incorporate the semiconductor device according to one of the first to sixth embodiments.

The moving body according to the present embodiment includes a driving force generating unit that generates driving force primarily used for the movement of the moving body, and one or both of a rotating body primarily used for the movement of the moving body. The driving force generating unit may be an engine, motor, etc. The rotating body may be a tire, wheel, ship's propeller, aircraft propeller, etc. The moving body may be for instance a bicycle, an automobile, a train, a vessel, an aircraft or a drone and the like. The moving body may have a body frame and a lamp provided on the body frame. The lamp may emit light for indicating the position of the body frame. The lamp has the organic light-emitting element according to the embodiment as described above.

Next, a description of an application example of the display device according to each embodiment as described above will be given. The display device can be used in a system that can be worn as a wearable device, such as smart glasses, HMDs or smart contacts. An imaging display device used in such an application example may have an imaging device capable of photoelectrically converting visible light, and a display device capable of emitting visible light.

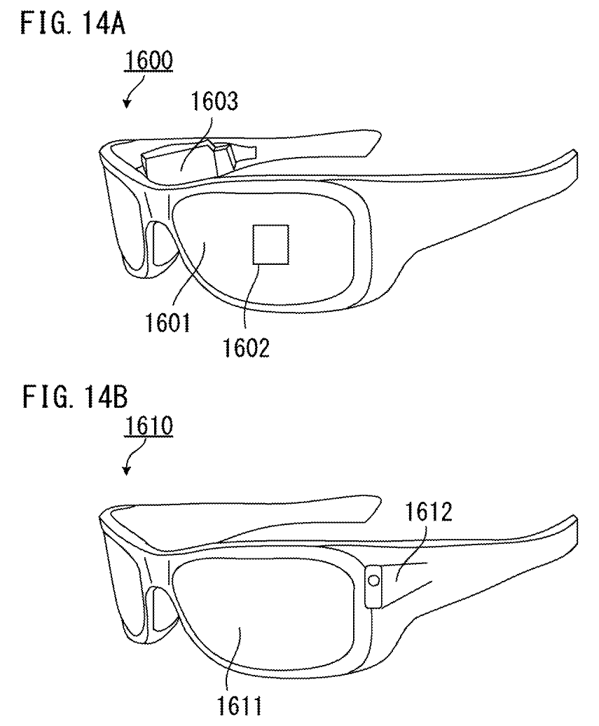

FIG. 14A illustrates spectacles 1600 (smart glasses) according to an application example of the display device having the organic light-emitting element of the present embodiment. An imaging device 1602 such as a CMOS sensor or a SPAD is provided on the front surface side of a lens 1601 of the spectacles 1600. A display device of the embodiments described above is provided on the back surface side of the lens 1601.

The spectacles 1600 further have a control device 1603. The control device 1603 functions as a power supply that supplies power to the imaging device 1602 and to the display device according to the embodiments. The control device 1603 controls the operations of the imaging device 1602 and of the display device. The lens 1601 has formed therein an optical system for condensing light onto the imaging device 1602.

FIG. 14B illustrates spectacles 1610 (smart glasses) according to another application example of the display device having the organic light-emitting element of the present embodiment. The spectacles 1610 have a control device 1612. The control device 1612 has mounted therein an imaging device corresponding to the imaging device 1602, and a display device. In a lens 1611 there is formed an optical system for projecting the light emitted by the display device in the control device 1612, such that an image is projected onto the lens 1611. The control device 1612 functions as a power supply that supplies power to the imaging device and to the display device, and controls the operations of the imaging device and of the display device. The control device may have a line-of-sight detection unit that detects the line of sight of the wearer. Infrared rays may be used herein for line-of-sight detection. An infrared light-emitting unit emits infrared light towards one eyeball of a user who is gazing at a display image. The infrared light emitted is reflected by the eyeball, and is detected by an imaging unit having a light-receiving element, whereby a captured image of the eyeball is obtained as a result. Impairment of the appearance of the image is reduced herein by having a reducing means for reducing light from the infrared light-emitting unit to the display unit, in a plan view.

The line of sight of the user with respect to the display image is detected on the basis of the captured image of the eyeball obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea.

More specifically, line-of-sight detection processing based on a pupillary-corneal reflection method is carried out herein. The line of sight of the user is detected by calculating a line-of-sight vector that represents the orientation (rotation angle) of the eyeball, on the basis of a Purkinje image and a pupil image included in the captured image of the eyeball, in accordance with a pupillary-corneal reflection method.

The display device having the organic light-emitting element according to one embodiment of the present disclosure may have an imaging device having a light-receiving element, and may control the display image of the display device on the basis of line-of-sight information about the user, from the imaging device.

Specifically, a first visual field area gazed at by the user and a second visual field area, other than the first visual field area, are determined in the display device on the basis of line-of-sight information. The first visual field area and the second visual field area may be determined by the control device of the display device; alternatively, the display device may receive visual field areas determined by an external control device. In a display area of the display device, the display resolution in the first visual field area may be controlled to be higher than the display resolution in the second visual field area. That is, the resolution in the second visual field area may set to be lower than that of the first visual field area.

The display area may have a first display area and a second display area different from the first display area, such that the display device selects the area of higher priority, from among the first display area and the second display area, on the basis of the line-of-sight information. The first display area and the second display area may be determined by the control device of the display device; alternatively, the display device may receive display areas determined by an external control device. The display device may control the resolution in a high-priority area so as to be higher than the resolution in areas other than high-priority areas. That is, the display device may lower the resolution in areas of relatively low priority.

Herein AI (Artificial Intelligence) may be used to determine the first visual field area and high-priority areas. The AI may be a model constructed to estimate, from an image of the eyeball, a line-of-sight angle, and the distance to an object lying ahead in the line of sight, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication from the external device.

In a case where the display device performs display control on the basis of on visual recognition detection, the display device can be preferably used in smart glasses further having an imaging device that captures images of the exterior. The smart glasses can display captured external information in real time.

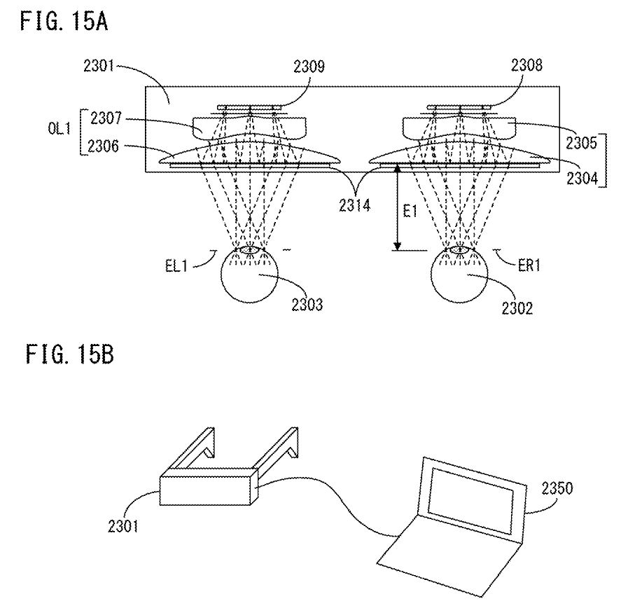

FIGS. 15A and 15B are schematic diagrams of a HMD (head mount display) 2301 serving as a display device according to an embodiment of the present disclosure. FIG. 15A is a schematic diagram illustrating the head mount display and an observer wearing the head mount display. The HMD 2301 is attached to the head of the observer. A reference sign 2302 denotes a right eye of the observer, and a reference sign 2303 denotes a left eye of the observer. Display lenses 2304 and 2305 form a right-eye ocular optical system OR1, while display lenses 2306 and 2307 form a left-eye ocular optical system OL1. Each of the ocular optical systems is a coaxial optical system configured to include the plurality of (two) display lenses. In an exit pupil ER1 of the right-eye ocular optical system OR1, the right eye 2302 of the observer is placed and, in an exit pupil ELb of the left-eye ocular optical system OL1, the left eye 2303 of the observer is placed. The exit pupil ER1 is provided at a position away from the right-eye ocular optical system OR1 by a distance E1. Likewise, the exit pupil EL1 is provided at a position away from the left-eye ocular optical system OL1 by the distance E1. On the surface (the surface on the right eye 2302 side) of the right-eye ocular optical system OR1 and on the surface (the surface on the left eye 2303 side) of the left-eye ocular optical system OL1, optical films 2314 for lens protection and light focusing are provided.

A reference sign 2308 and a reference sign 2309 respectively denote display devices for the right eye and the left eye. These display devices may be the display devices according to the above embodiments. FIG. 15B is a schematic diagram illustrating an example in which the display devices according to one of the embodiments of the present disclosure are connected to an external device, and shows outer appearance of the HMD 2301 and a personal computer 2350 connected thereto. Each of the display devices displays a display image (original image) corresponding to an image signal output from the personal computer 2350. In this mode, wired connection is provided, but wireless connection may also be provided. Alternatively, the HMD 2301 may also be a device which has an image processing device mounted therein and operates in a stand-alone manner.

The ocular optical systems OR1 and OL1 guide light from the display devices 2308 and 2309 to the exit pupils ER1 and EL1, and thereby project enlarged virtual images of display image onto the right eye 2302 and the left eye 2303 of the observer. This allows the observer to observe the display image (virtual images thereof) displayed on the display devices 2308 and 2309 through the ocular optical systems OR1 and OL1.

The HMD 2301 may also have a control device, though not shown. The control device functions as a power source that supplies power to the display devices 2308 and 2309, and also controls operations of the display devices 2308 and 2309.

The embodiments described above may be appropriately modified without departing from the technical idea. Note that the disclosure of the present specification includes not only the matters described in the present specification but also all matters that may be grasped from the present specification and the drawings attached to the present specification.

According to the present disclosure, it is possible to provide a technology that can reduce a wiring area used in a functional element to save space, and reduce the size of a semiconductor device.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-046383, filed on March 21, 2025 hereby incorporated by reference herein in its entirety.

What is claimed is:

1. A semiconductor device comprising:
a first substrate having an element region where a functional element is disposed;
a light-transmissive substrate overlapping at least a portion of the element region when the first substrate is viewed in plan view; and
a second substrate having an operating circuit for the functional element,
wherein the first substrate and the light-transmissive substrate are bonded to each other,
wherein the second substrate is disposed on a side opposite to the first substrate side with respect to the light-transmissive substrate, and
wherein the first substrate and the second substrate are electrically connected via wiring formed in the light-transmissive substrate.

2. The semiconductor device according to claim 1,
wherein the functional element includes at least an image capturing element or a display element.

3. The semiconductor device according to claim 1,
wherein the light-transmissive substrate is formed by using at least one of glass, quartz, and sapphire.

4. The semiconductor device according to claim 1,
wherein the operating circuit includes at least a signal processing circuit or an amplification circuit.

5. The semiconductor device according to claim 1,
wherein the second substrate is bonded onto a flexible substrate having wiring for operating the functional element, and
wherein the second substrate is electrically connected to the first substrate via the flexible substrate.

6. The semiconductor device according to claim 1,
wherein, when viewed in plan view, the light-transmissive substrate is larger than the first substrate and the second substrate.

7. The semiconductor device according to claim 1,
wherein the wiring penetrates through the light-transmissive substrate.

8. The semiconductor device according to claim 1,
wherein, in a depressed portion formed in the light-transmissive substrate, the second substrate is disposed.

9. A semiconductor device comprising:
a first substrate having an element region where a functional element is disposed;
a light-transmissive substrate overlapping at least a portion of the element region when the first substrate is viewed in plan view; and
a second substrate having an operating circuit for the functional element,
wherein the first substrate and the light-transmissive substrate are bonded to each other,
wherein the second substrate is disposed on the first substrate side with respect to the light-transmissive substrate, and
wherein the first substrate and the second substrate are electrically connected by wiring formed on the first substrate side of the transmissive substrate.

10. The semiconductor device according to claim 9,
wherein the functional element includes at least an image capturing element or a display element.

11. The semiconductor device according to claim 9,
wherein the light-transmissive substrate is formed by using at least one of glass, quartz, and sapphire.

12. The semiconductor device according to claim 9,
wherein the operating circuit includes at least a signal processing circuit or an amplification circuit.

13. The semiconductor device according to claim 9,
wherein the second substrate is bonded onto a flexible substrate having wiring for operating the functional element, and
wherein the second substrate is electrically connected to the first substrate via the flexible substrate.

14. The semiconductor device according to claim 9,
wherein, when viewed in plan view, the light-transmissive substrate is larger than the first substrate and the second substrate.

15. The semiconductor device according to claim 9, wherein, in a depressed portion formed in the light-transmissive substrate, the second substrate is disposed.

16. A display device comprising:
a display unit having the semiconductor device according to claim 1; and
a control circuit that controls the display unit.

17. A display device comprising:
a display unit having the semiconductor device according to claim 9; and
a control circuit that controls the display unit.

18. A photoelectric conversion device comprising:
an optical unit having a plurality of lenses;
an image capturing element that receives light having passed through the optical unit; and
a display unit that displays an image captured by the image capturing element,
wherein the display unit has the semiconductor device according to claim 1.

19. A photoelectric conversion device comprising:
an optical unit having a plurality of lenses;
an image capturing element that receives light having passed through the optical unit; and
a display unit that displays an image captured by the image capturing element,
wherein the display unit has the semiconductor device according to claim 9.

20. Electronic equipment comprising:
a display unit having the semiconductor device according to claim 1;
a casing provided with the display unit; and
a communication unit provided in the casing to communicate with the outside.

21. Electronic equipment comprising:
a display unit having the semiconductor device according to claim 9;
a casing provided with the display unit; and
a communication unit provided in the casing to communicate with the outside.
